(19) United States
(12) Patent Application Publication
(10) Pub. No.: US 2015/0091062 A1
(43) Pub. Date: Apr. 2, 2015

(54) SEMICONDUCTOR ELEMENT, SEMICONDUCTOR DEVICE, METHOD FOR MANUFACTURING SEMICONDUCTOR ELEMENT, AND METHOD FOR MANUFACTURING SEMICONDUCTOR DEVICE

(71) Applicant: Kabushiki Kaisha Toshiba, Tokyo (JP)

(72) Inventor: Takako Motai, Yokohama Kanagawa (JP)

(21) Appl. No.: 14/476,313

(22) Filed: Sep. 3, 2014

(30) Foreign Application Priority Data
Oct. 2, 2013 (JP) 2013-207091

(51) Int. Cl. H01L 23/60; H01L 21/768; H01L 21/28; H01L 29/778; H01L 29/66

(52) U.S. Cl. CPC H01L 23/60; H01L 29/778; H01L 29/66431; H01L 21/28; H01L 21/768
USPC 257/194; 438/618

(57) ABSTRACT

According to one embodiment, a semiconductor element includes a first semiconductor layer, a second semiconductor layer, a first electrode, a second electrode, a control electrode, a pad unit, an insulating layer, and a conductor. The second semiconductor layer is provided on the first semiconductor layer. The first electrode is provided on the second semiconductor layer. The second electrode is provided on the second semiconductor layer. The control electrode is provided on the second semiconductor layer. The pad unit is provided on the second semiconductor layer. The pad unit is electrically connected to the control electrode. The insulating layer is provided on the second semiconductor layer. The insulating layer has an opening. The conductor is provided on the insulating layer. The conductor covers at least a part of the opening.

### CROSS-REFERENCE TO RELATED APPLICATIONS

This application is based upon and claims the benefit of priority from Japanese Patent Application No. 2013-207091, filed on Oct. 2, 2013; the entire contents of which are incorporated herein by reference.

### FIELD

Embodiments described herein relate generally to a semiconductor element, a semiconductor device, a method for manufacturing semiconductor element, and a method for manufacturing semiconductor device.

### BACKGROUND

While a semiconductor element, for example such as a HEMT (High Electron Mobility Transistor), is suitable for high-speed operation because it has a small gate capacitance, the ESD (electro-static discharge) resistance of the semiconductor element is low. As the countermeasure against ESD of the device, a method for incorporating a protection diode into the device can be contemplated. However, this protection diode increases the device area or interferes with the operation of the device and thus this method has not been put into a practical use yet. In such a semiconductor element, it is desirable to improve the ESD resistance without interfering with the operation of the device and without an increase in the device area. Moreover, a semiconductor device using a semiconductor element having a high ESD resistance is desired.

### BRIEF DESCRIPTION OF THE DRAWINGS

FIG. 1 is a plan view schematically showing a semiconductor element according to a first embodiment;

FIG. 2A and FIG. 2B are partial sectional views schematically showing a part of the semiconductor element according to the first embodiment;

FIG. 3 is an equivalent circuit diagram schematically showing the semiconductor element according to the first embodiment;

FIG. 4 is a schematic view showing a semiconductor device according to the first embodiment;

FIG. 5A to FIG. 5H are cross sectional views schematically showing the order of the manufacturing processes of the semiconductor element according to the first embodiment;

FIG. 6A to FIG. 6C are cross sectional views schematically showing the order of the manufacturing processes of the semiconductor device according to the first embodiment;

FIG. 7 is a partial sectional view schematically showing a part of another semiconductor element according to the first embodiment;

FIG. 8A and FIG. 8B are the schematic views showing a semiconductor element according to a second embodiment;

FIG. 9A to FIG. 9C are cross sectional views schematically showing the order of the manufacturing processes of the semiconductor element according to the second embodiment;

FIG. 10 is a plan view schematically showing a semiconductor element according to a third embodiment;

FIG. 11A and FIG. 11B are partial sectional views schematically showing a part of the semiconductor element according to the third embodiment; and

FIG. 12 is an equivalent circuit diagram schematically showing the semiconductor element according to the third embodiment.

### DETAILED DESCRIPTION

According to one embodiment, a semiconductor element includes a first semiconductor layer, a second semiconductor layer, a first electrode, a second electrode, a control electrode, a pad unit, an insulating layer, and a conductor. The second semiconductor layer is provided on the first semiconductor layer. The first electrode is provided on the second semiconductor layer. The second electrode is provided on the second semiconductor layer. The control electrode is provided on the second semiconductor layer. The pad unit is provided on the second semiconductor layer. The pad unit is electrically connected to the control electrode. The insulating layer is provided on the second semiconductor layer. The insulating layer has an opening. The conductor is provided on the insulating layer. The conductor covers at least a part of the opening.

According to another embodiment, a semiconductor device includes a substrate, a semiconductor element, and a wiring. The substrate includes a support unit and a wiring electrode. The semiconductor element is provided on the support unit. The semiconductor element includes a first semiconductor layer, a second semiconductor layer, a first electrode, a second electrode, a control electrode, a pad unit, and an insulating layer. The second semiconductor layer is provided on the first semiconductor layer. The first electrode is provided on the second semiconductor layer. The second electrode is provided on the second semiconductor layer. The control electrode is provided on the second semiconductor layer. The pad unit is provided on the second semiconductor layer. The pad unit is electrically connected to the control electrode. The insulating layer is provided on the second semiconductor layer. The insulating layer has an opening on the pad unit. The wiring electrically connects the wiring electrode and the pad unit.

According to another embodiment, a semiconductor device includes a substrate, a semiconductor element, and a wiring. The substrate includes a support unit and a wiring electrode. The semiconductor element is provided on the support unit. The semiconductor element includes a first semiconductor layer, a second semiconductor layer, a first electrode, a second electrode, a control electrode, a pad unit, an insulating layer, and at least one of a conductor and a conductive film. The second semiconductor layer is provided on the first semiconductor layer. The first electrode is provided on the second semiconductor layer. The second electrode is provided on the second semiconductor layer. The control electrode is provided on the second semiconductor layer. The pad unit is provided on the second semiconductor layer. The pad unit is electrically connected to the control electrode. The insulating layer is provided on the second semiconductor layer. The insulating layer has an opening. The conductor is provided on the insulating layer and covers at least a part of the opening. The conductive film is provided on the second semiconductor layer inside the opening. The wiring electrically connects the wiring electrode and the pad unit.

According to another embodiment, a method is disclosed for manufacturing a semiconductor element. The method can include forming a first semiconductor layer on a substrate. The method can include forming a second semiconductor layer on the first semiconductor layer. The method can include forming a first electrode and a second electrode on the second semiconductor layer. The method can include forming a control electrode on the first semiconductor layer. The method can include forming a pad unit provided on the second semiconductor layer and electrically connected to the control electrode. The method can include forming an insulating layer having an opening on the first semiconductor layer. The method can include forming a conductor on the insulating layer. The conductor covers at least a part of the opening.

According to another embodiment, a method is disclosed for manufacturing a semiconductor device. The method can include providing a semiconductor element on a mounting substrate. The mounting substrate includes a support unit and a wiring electrode. The semiconductor element includes a first semiconductor layer, a second semiconductor layer, a first electrode, a second electrode, a control electrode, a pad unit, an insulating layer, and a conductor. The second semiconductor layer is provided on the first semiconductor layer. The first electrode is provided on the second semiconductor layer. The second electrode is provided on the second semiconductor layer. The control electrode is provided on the second semiconductor layer. The pad unit is provided on the second semiconductor layer. The pad unit is electrically connected to the control electrode. The insulating layer is provided on the second semiconductor layer. The insulating layer has an opening. The conductor is provided on the insulating layer. The conductor covers at least a part of the opening. The semiconductor element is provided on the support unit. The method can include short-circuiting or insulating an electric connection between the pad unit and the conductor. The method can include electrically connecting the wiring electrode and the pad unit using a wiring.

Various embodiments will be described hereinafter with reference to the accompanying drawings.

The drawings are schematic or conceptual; and the relationships between the thicknesses and widths of portions, the proportions of sizes among portions, etc., are not necessarily the same as the actual values thereof. Further, the dimensions and the proportions may be illustrated differently among the drawings, even for identical portions.

In the specification and the drawings of the application, components similar to those described in regard to a drawing thereinabove are marked with like reference numerals, and a detailed description is omitted as appropriate.

### First Embodiment

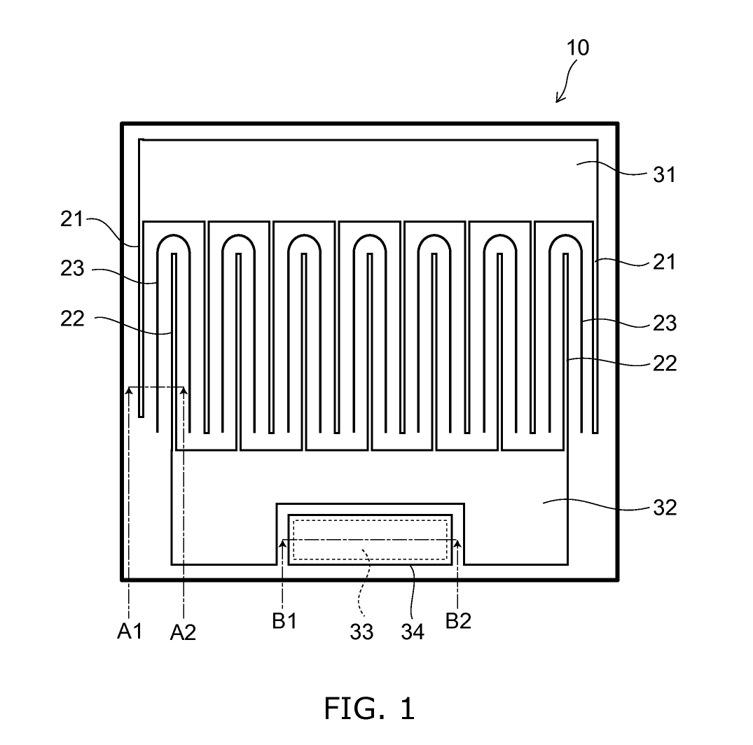

FIG. 1 is a plan view schematically showing a semiconductor element according to a first embodiment. In this plan view, an insulating layer 19 is omitted.

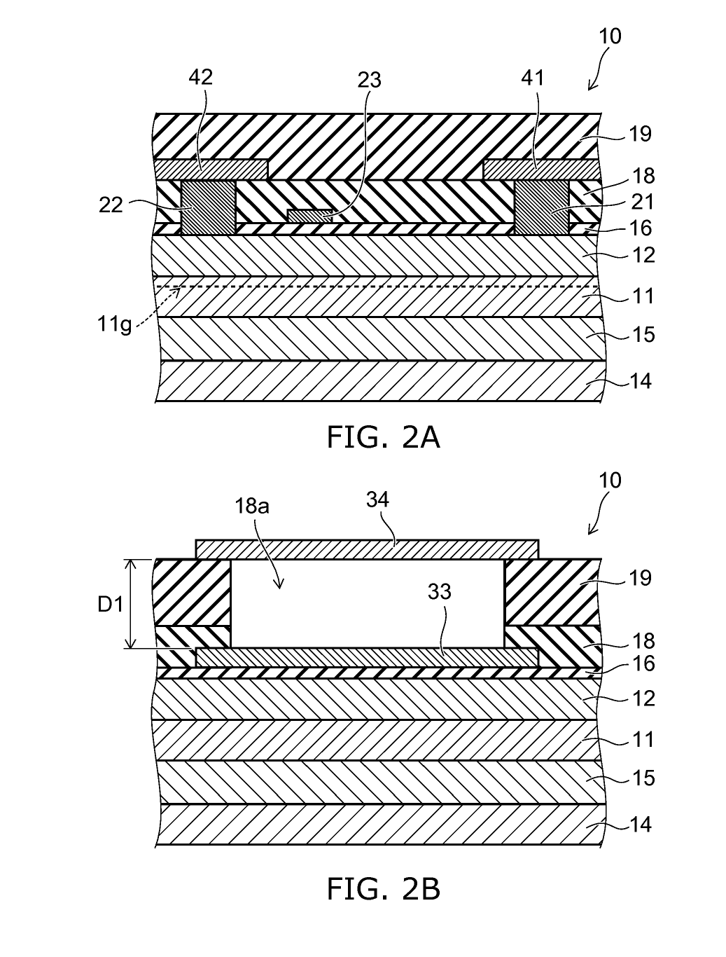

FIG. 2A and FIG. 2B are partial sectional views schematically showing a part of the semiconductor element according to the first embodiment.

FIG. 2A schematically shows the cross section along an A1-A2 line of FIG. 1. FIG. 2B schematically shows the cross section along a B1-B2 line of FIG. 1.

As shown in FIG. 1, FIG. 2A and FIG. 2B, a semiconductor element 10 includes a first semiconductor layer 11, a second semiconductor layer 12, a substrate 14, a foundation layer 15, a gate insulating film 16, an insulating layer 18, an insulating layer 19, a drain electrode 21 (a first electrode), a source electrode 22 (a second electrode), a gate electrode 23 (a gate electrode), a drain pad 31, a source pad 32, a gate pad 33 (a pad unit), a conductor 34, a drain interconnection 41, and a source interconnection 42. In the example, the semiconductor element 10 is a so-called HEMT.

As the substrate 14, a silicon substrate is used, for example. The substrate 14 may be, for example, a SiC (silicon carbide) substrate, a sapphire substrate, or the like. The substrate 14 may be removed, for example, by back grinding, laser lift off, or the like after formation of the device.

The foundation layer 15 is provided on the substrate 14. The foundation layer 15 includes nitride semiconductor, for example. The foundation layer 15 includes AlₐGa₁₋ₐN (0≦a≦1), for example. The foundation layer 15 includes a plurality of nitride semiconductor layers, for example. The foundation layer 15 includes a plurality of AlN layers, a plurality of AlGaN layers, and a plurality of GaN layers, for example. These layers are periodically stacked in the order of AlN layer-AlGaN layer-GaN layer in the stacking direction of the substrate 14 and foundation layer 15, for example. That is, the foundation layer 15 is a superlattice layer, for example. The foundation layer 15 is not limited thereto, but may be, for example, a stacked film including a plurality of AlGaN layers whose composition ratio of Al is gradually varied between AlN and GaN. The foundation layer 15 may be, for example, one layer (a so-called graded layer) whose composition ratio of Al is continuously varied from AlN toward GaN. The foundation layer 15 is provided as required, and can be omitted.

The first semiconductor layer 11 is provided on the foundation layer 15. The first semiconductor layer 11 includes nitride semiconductor, for example. The first semiconductor layer 11 includes Alₓ₁Ga₁₋ₓ₁N (0≦x1<1), for example. The first semiconductor layer 11 is a GaN layer, for example. Moreover, the first semiconductor layer 11 is non-doped, for example. The first semiconductor layer 11 does not include an impurity, for example.

The second semiconductor layer 12 is provided on the first semiconductor layer 11. The second semiconductor layer 12 includes nitride semiconductor, for example. The second semiconductor layer 12 includes Alₓ₂Ga₁₋ₓ₂N (x1<x2<1), for example. The composition ratio of Al of the second semiconductor layer 12 is higher than the composition ratio of Al of the first semiconductor layer 11, for example. The second semiconductor layer 12 is an AlGaN layer, for example. Moreover, the second semiconductor layer 12 is non-doped or is of an n-type, for example. The second semiconductor layer 12 does not include an impurity or includes an n-type impurity, for example.

For example, it may be possible to set the first semiconductor layer 11 to an AlGaN layer and set the second semiconductor layer 12 to another AlGaN layer whose Al composition ratio is higher than the Al composition ratio of the first semiconductor layer 11. The material of the first semiconductor layer 11 and the material of the second semiconductor layer 12 are not limited to nitride semiconductor. For example, it may be possible to set the first semiconductor layer 11 to a GaAs layer and set the second semiconductor layer 12 to an AlGaAs layer.

The first semiconductor layer 11 is a channel layer, for example, and the second semiconductor layer 12 is a barrier layer, for example. The first semiconductor layer 11 is joined to the second semiconductor layer 12 by a heterojunction.

As described above, the composition ratio of Al of the second semiconductor layer 12 is higher than the composition ratio of Al of the first semiconductor layer 11. That is, the lattice constant of the second semiconductor layer 12 is smaller than the lattice constant of the first semiconductor layer 11. This causes a distortion in the second semiconductor layer 12, so that Piezo effect causes piezo polarization in the second semiconductor layer 12. Thus, a two-dimensional electron gas 11g is formed in a vicinity of an interface with the second semiconductor layer 12 in the first semiconductor layer 11.

The gate insulating film 16 is provided on the second semiconductor layer 12. For example, SiO₂, SiN, Al₂O₃, TiO₂, Ta₂O₅, HfO₂, ZrO₂, or the like is used for the gate insulating film 16. The gate insulating film 16 is provided as required, and can be omitted.

The drain electrode 21 is provided on the second semiconductor layer 12. The drain electrode 21 is in contact with the second semiconductor layer 12, for example. The drain electrode 21 is in ohmic contact with the second semiconductor layer 12, for example.

The source electrode 22 is provided on the second semiconductor layer 12. The source electrode 22 is disposed on the second semiconductor layer 12 so as to be separated from the drain electrode 21. The source electrode 22 is in contact with the second semiconductor layer 12, for example. The source electrode 22 is in ohmic contact with the second semiconductor layer 12, for example.

The gate electrode 23 is provided between the drain electrode 21 and the source electrode 22. The gate electrode 23 is disposed so as to be separated from each of the drain electrode 21 and the source electrode 22. Moreover, in the example, the gate electrode 23 is provided on the gate insulating film 16.

In the semiconductor element 10, the concentration of the two-dimensional electron gas 11g under the gate electrode 23 increases or decreases by controlling the voltage applied to the gate electrode 23. Thus, a current flowing between the drain electrode 21 and the source electrodes 22 is controlled.

Moreover, in the example, each of the drain electrode 21, source electrode 22, and gate electrode 23 is provided in plurality. For example, each of the plurality of gate electrodes 23 is provided between each of the plurality of drain electrodes 21 and each of the plurality of source electrodes 22. For example, a stacked film of Ti/AI is used for the drain electrode 21, the source electrode 22, and the gate electrode 23.

The drain pad 31 is electrically connected to each of the plurality of drain electrodes 21. The source pad 32 is electrically connected to each of the plurality of source electrodes 22. The gate pad 33 is electrically connected to each of the plurality of gate electrodes 23. The drain pad 31, the source pad 32, and the gate pad 33 are used for electric connection to the outside, for example. For example, the drain pad 31, the source pad 32, and the gate pad 33 are so-called bonding pads.

The drain interconnection 41 is provided on the drain electrode 21, for example. The drain interconnection 41 is electrically connected to the drain electrode 21. The drain interconnection 41 is electrically connected to each of the plurality of drain electrodes 21, for example. Moreover, the drain interconnection 41 is electrically connected to the drain pad 31. That is, the drain interconnection 41 electrically connects each drain electrode 21 to the drain pad 31.

The source interconnection 42 is provided on the source electrode 22, for example. The source interconnection 42 is electrically connected to the source electrode 22. The source interconnection 42 is electrically connected to each of the plurality of source electrodes 22, for example. Moreover, the source interconnection 42 is electrically connected to the source pad 32. That is, the source interconnection 42 electrically connects each source electrode 22 to the source pad 32. The gate electrode 23 and the gate pad 33 are provided on the same plane, and are connected to each other with a non-illustrated wiring.

The insulating layer 18 and the insulating layer 19 are provided on the gate insulating film 16. The insulating layer 18 fills portions other than the respective electrodes 21 to 23 on the gate insulating film 16, for example. The insulating layer 19 is provided on the insulating film 18 and covers the respective interconnections 41 and 42, for example. An opening 18a is provided in the insulating layer 18 or the insulating layer 19, and in a stacked layer thereof. In the example, the opening 18a is provided on the gate pad 33. The opening 18a exposes at least a part of the gate pad 33, for example.

The conductor 34 is provided on the insulating layer 19 and covers at least a part of the opening 18a. In the example, the conductor 34 opposes at least a part of the gate pad 33. The conductor 34 opposes the whole gate pad 33, for example. The conductor 34 opposes the gate pad 33 with a space therebetween. Thus, the conductor 34 is capacitively coupled with the gate pad 33. A metallic material, for example such as Al, Cu, or Ag, is used for the conductor 34. The material of the conductor 34 may be an arbitrary material that is conductive and capacitively coupled with the gate pad 33, for example. A distance D1 between the gate pad 33 and the conductor 34 is approximately several hundreds of nm to 1 μm, for example. The portion between the gate pad 33 and the conductor 34 is an air layer, for example. For example, a dielectric material may be provided between the gate pad 33 and the conductor 34.

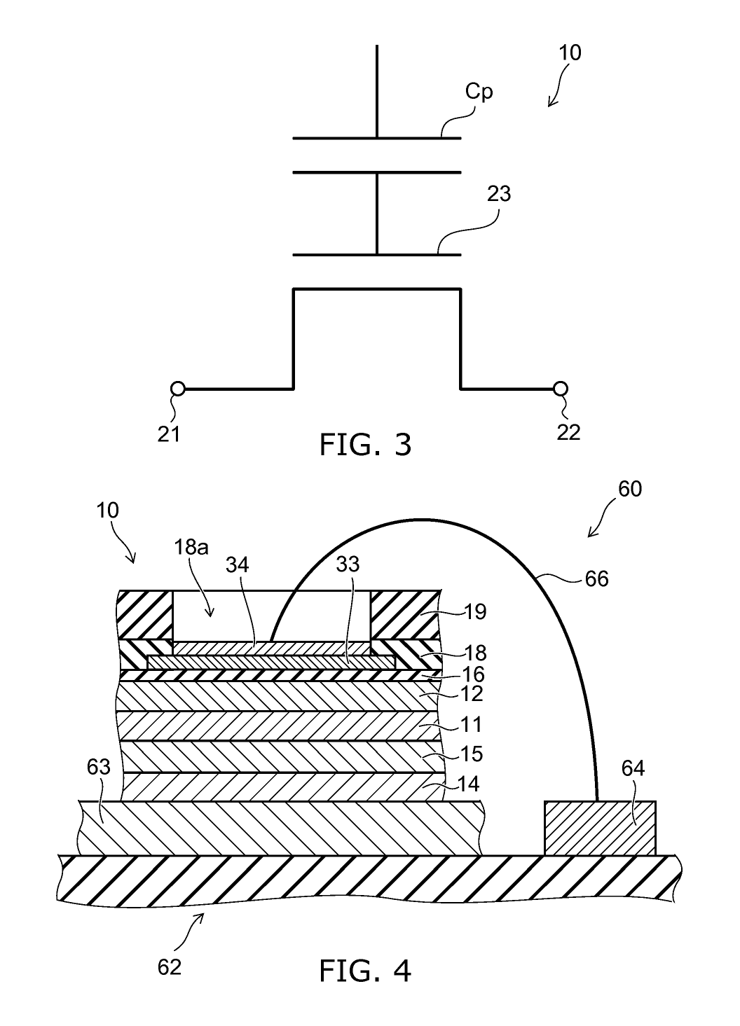

FIG. 3 is an equivalent circuit diagram schematically showing the semiconductor element according to the first embodiment.

As shown in FIG. 3, a protection capacitor Cp electrically connected to the gate electrode 23 is provided in the semiconductor element 10. The protection capacitor Cp is formed by capacitive coupling between the gate pad 33 and the conductor 34. In this manner, the conductor 34 forms the protection capacitor Cp along with the gate pad 33. The conductor 34 is electrically connected to the gate electrode 23 via the protection capacitor Cp, for example. On the other hand, the conductor 34 is electrically insulated from each of the drain electrode 21 and the source electrode 22, for example.

FIG. 4 is a schematic view showing a semiconductor device according to the first embodiment.

As shown in FIG. 4, a semiconductor device 60 includes the above-described semiconductor element 10, a mounting substrate 62, and a wiring 66. The mounting substrate 62 includes a support unit 63 and a wiring electrode 64.

The semiconductor element 10 is provided on the support unit 63 of the mounting substrate 62. The mounting substrate 62 is a frame of a semiconductor package, for example. The support unit 63 is a die pad, for example. The wiring electrode 64 is a lead frame, for example. The mounting substrate 62 may be, for example, a wiring substrate or the like. In this case, the support unit 63 is in an arbitrary mounting place on the substrate, for example. The wiring electrode 64 is an electrode (a so-called land) provided on the substrate, for example.

In the case where the semiconductor element 10 is used for the semiconductor device 60, the conductor 34 is deformed at least either thermally or mechanically after the semiconductor element 10 is provided on the support unit 63. Thus, the conductor 34 contacts the gate pad 33. That is, the electric connection between the gate pad 33 and the conductor 34 is short-circuited.

Therefore, in the semiconductor device 60 using the semiconductor element 10, the conductor 34 is provided inside the opening 18a. In the example, the conductor 34 that directly contacts the gate pad 33 and is short-circuited thereto is provided in a lower part of the opening 18a. In the case where a semiconductor element having a dielectric material provided between the gate pad 33 and the conductor 34 is used for the semiconductor device, the conductor 34 is deformed at least either thermally or mechanically, as with the case described above, whereby at least a part of the conductor 34 directly contacts the gate pad 33 and is electrically connected thereto.

The wiring 66 electrically connects the gate pad 33 and the wiring electrode 64. In the example, the wiring electrode 64 is electrically connected to the gate pad 33 via the wiring 66 and the conductor 34. For example, one end of the wiring 66 is in contact with the wiring electrode 64 and the other end of the wiring 66 is in contact with the conductor 34. Thus, the wiring electrode 64 and the conductor 34 are electrically connected via the wiring 66. The wiring 66 is a bonding wire, for example.

In the above, while a case is described where the conductor 34 directly contacts the gate pad and is electrically connected thereto, the conductor 34 may be destroyed or removed. In order to perform a high-speed operation in the semiconductor device 60, the gate capacitance may be reduced. By destroying or removing the conductor 34, the coupling capacitance with the gate pad 33 is reduced or eliminated, and thus it is possible to reduce the capacitance of the protection capacitor Cp of the semiconductor element 10. In this case, one end of the wiring 66 is in contact with the wiring electrode 64 and the other end is directly connected to the gate pad 33.

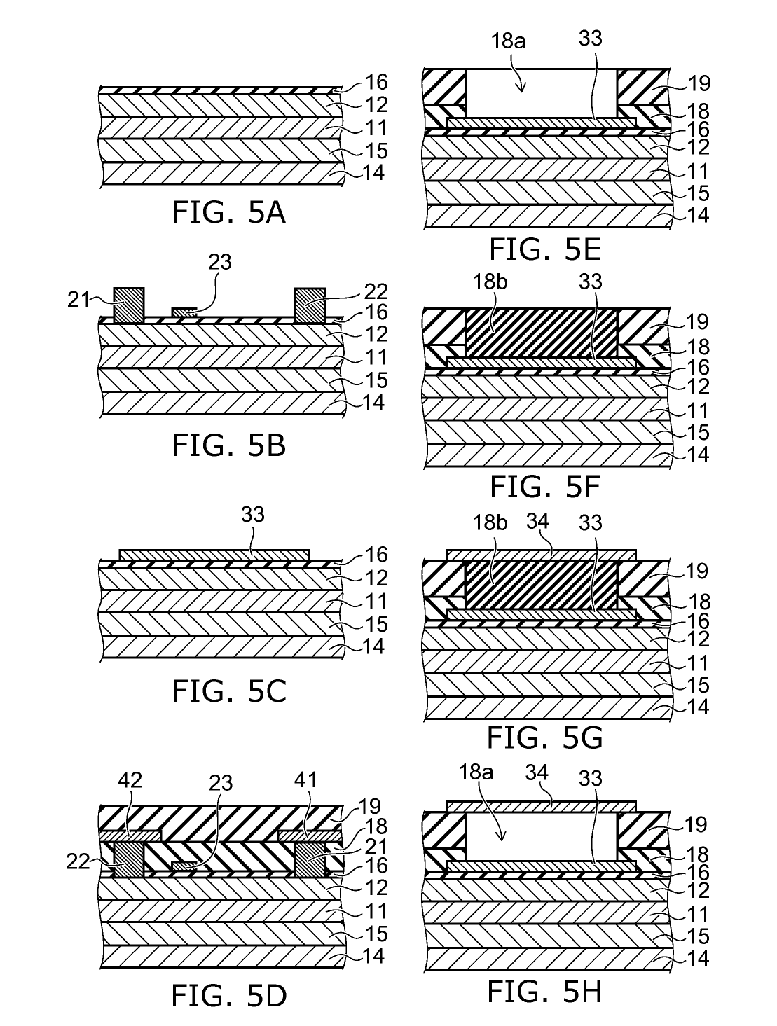

FIG. 5A to FIG. 5H are cross sectional views schematically showing the order of the manufacturing processes of the semiconductor element according to the first embodiment.

As shown in FIG. 5A, in manufacturing the semiconductor element 10, firstly the foundation layer 15 is formed on the substrate 14. On the foundation layer 15, the first semiconductor layer 11 including GaN is formed. On the first semiconductor layer 11, the second semiconductor layer 12 including AlGaN is formed. On the second semiconductor layer 12, the gate insulating film 16 including SiN is formed.

Next, a part of the gate insulating film 16 is removed by etching using a mask, and as shown in FIG. 5B, the drain electrode 21 and the source electrode 22 are formed on the second semiconductor layer 12. For example, a multilayer film of Ti/Al is formed as the drain electrode 21 and the source electrode 22. Subsequently, for example, by performing heat treatment of no less than 700° C., the drain electrode 21 and the source electrode 22 are in ohmic contact with the second semiconductor layer 12. The gate electrode 23 is formed on the gate insulating film 16 between the drain electrode 21 and the source electrode 22. Thus, a HEMT structure is completed.

As shown in FIG. 5C, the gate pad 33 is formed on the gate insulating film 16 in a region different from the region where the HEMT structure is formed. The gate electrode 23 and the gate pad 33 are electrically connected using a non-illustrated lead wiring.

As shown in FIG. 5D, on the gate insulating film 16, the insulating layer 18 is formed and also the drain interconnection 41 and the source interconnection 42 are formed. Moreover, the insulating layer 19 is formed on the insulating layer 18, the drain interconnection 41, and the source interconnection 42.

As shown in FIG. 5E, the opening 18a is formed in the insulating layer 18 and the insulating layer 19. In the example, the opening 18a is formed on the gate pad 33 so as to expose at least a part of the gate pad 33.

As shown in FIG. 5F, a sacrifice layer 18b is formed inside the opening 18a to fill the opening 18a. For example, a resist is used for the sacrifice layer 18b.

As shown in FIG. 5G, the conductor 34 is formed on the sacrifice layer 18b. At this time, the conductor 34 is formed so as to expose a part of the sacrifice layer 18b. That is, the conductor 34 does not plug the opening 18a.

As show in FIG. 5H, the sacrifice layer 18b is removed to hollow out the inside of the opening 18a. For example, the sacrifice layer 18b is melted with solvent, O₂ plasma, or the like. Then, the sacrifice layer 18b is removed by discharging the melted sacrifice layer 18b from an opening part that is not covered with the conductor 34.

Thus, the semiconductor element 10 is completed.

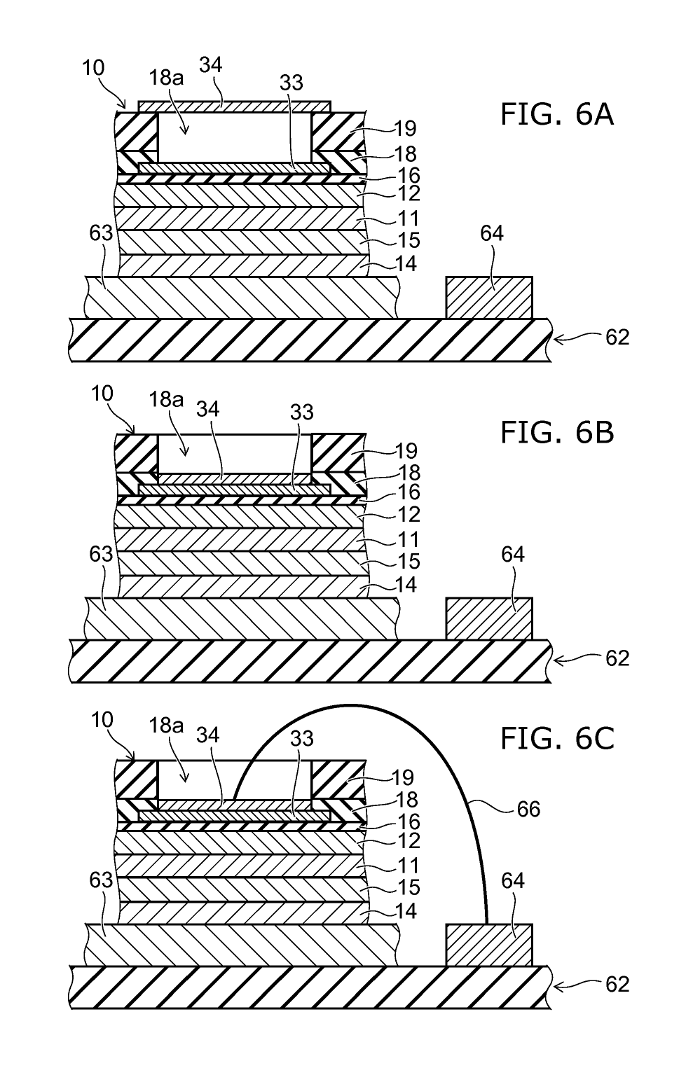

FIG. 6A to FIG. 6C are cross sectional views schematically showing the order of the manufacturing processes of the semiconductor device according to the first embodiment.

As shown in FIG. 6A, in manufacturing the semiconductor device 60, firstly the semiconductor element 10 is provided on the support unit 63 of the mounting substrate 62.

As shown in FIG. 6B, the electric connection between the gate pad 33 and the conductor 34 is short-circuited by deforming the conductor 34 at least either thermally or mechanically.

As shown in FIG. 6C, the gate pad 33 and the wiring electrode 64 are electrically connected via the wiring 66. For example, the gate pad 33 and the wiring electrode 64 are electrically connected by connecting the conductor 34 and the wiring electrode 64 via the wiring 66.

Thus, the semiconductor device 60 is completed.

In the semiconductor element 10 according to the embodiment, the protection capacitor Cp is formed by providing the conductor 34 on the gate pad 33. Thus, the gate capacitance can be increased to improve the ESD resistance of the semiconductor element 10 during the assembly processes, in particular, including dicing, mounting, and the like. For example, the voltage applied to the gate pad 33 can be reduced. Moreover, when compared with the case where a protection diode or the like is provided, an increase in device area can be also suppressed.

Furthermore, in the case where the semiconductor element 10 is used for the semiconductor device 60, the conductor 34 is thermally and/or mechanically deformed for direct conduction between the conductor 34 and the gate pad 33, before bonding that is performed in the final stage of the assembly. Thus, while the capacitance of the protection capacitor Cp of the semiconductor element 10 decreases, the capacitance and/or resistance that interfere with the high-speed operation of the semiconductor device 60 can be reduced and the adverse effects, such as characteristic degradation, can be suppressed.

In this manner, in the semiconductor element 10, it is possible to improve the ESD resistance while suppressing the interference with the operation of the device and/or an increase in device area. Moreover, in the example, the conductor 34 is provided on the gate pad 33. Thus, the gate pad 33 can be also physically protected with the conductor 34.

Moreover, in the case where the semiconductor device 60 is formed, the capacitance of the protection capacitor Cp is attempted to be reduced by short-circuiting the electric connection between the gate pad 33 and the conductor 34. Alternatively, by destroying the conductor 34 or removing the conductor 34, the electric connection between the gate pad 33 and the conductor 34 is insulated to reduce the capacitance of the protection capacitor Cp. Thus, the semiconductor device 60 can operate at high speed.

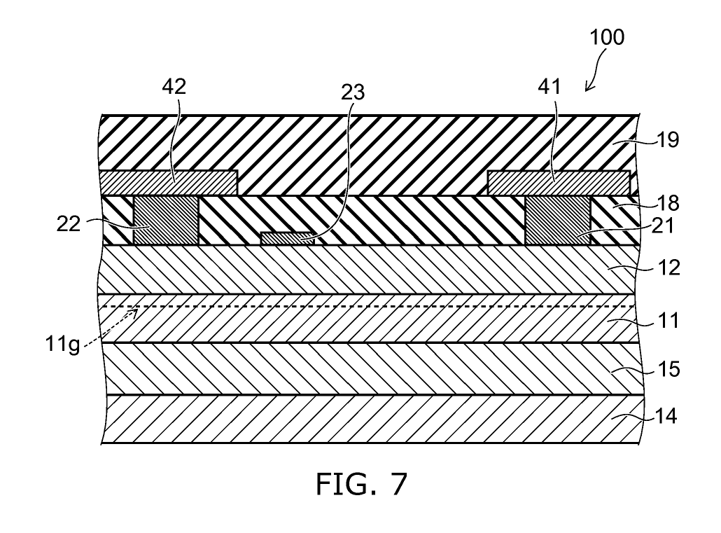

FIG. 7 is a partial sectional view schematically showing a part of another semiconductor element according to the first embodiment.

As shown in FIG. 7, in a semiconductor element 100, the gate insulating film 16 is omitted and the gate electrode 23 is provided on the second semiconductor layer 12. In the semiconductor element 100, the gate electrode 23 is in contact with the second semiconductor layer 12, for example. The gate electrode 23 is in Schottky contact with the second semiconductor layer 12, for example.

Also in the semiconductor element 100, the current flowing between the drain electrode 21 and the source electrode 22 can be controlled in accordance with the voltage applied to the gate electrode 23. The gate insulating film 16 can be omitted in this manner.

### Second Embodiment

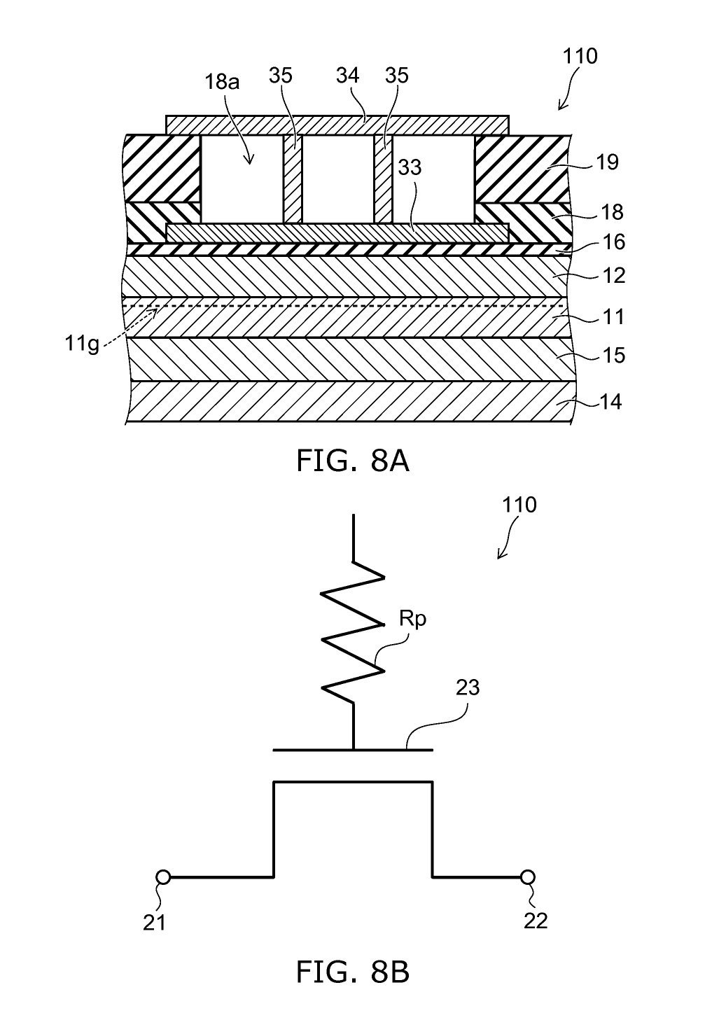

FIG. 8A and FIG. 8B are the schematic views showing a semiconductor element according to a second embodiment.

FIG. 8A is a partial sectional view schematically showing a part of a semiconductor element 110.

FIG. 8B is an equivalent circuit diagram schematically showing the semiconductor element 110.

As shown in FIG. 8A, the semiconductor element 110 further includes a resistor 35. The semiconductor element 110 includes a plurality of the resistors 35, for example. The resistor 35 is provided between the gate pad 33 and the conductor 34. The resistor 35 is electrically connected to each of the gate pad 33 and the conductor 34. The resistor 35 is in contact with each of the gate pad 33 and the conductor 34, for example. That is, in the semiconductor element 110, the conductor 34 is electrically connected to the gate pad 33 via the resistor 35. For example, a metal oxide of Nichrome (NiCr), tantalum nitride (TaN), or the like is used for the resistor 35.

As shown in FIG. 8B, in the semiconductor element 110, a protection resistor Rp electrically connected to the gate electrode 23 is provided. The protection resistor Rp is formed of the resistor 35. In this manner, the resistor 35 forms the protection resistor Rp.

In this manner, in the semiconductor element 110, the protection resistor Rp is formed of the resistor 35. Also in the case where the protection resistor Rp is provided, the voltage applied to the gate pad 33 can be reduced, for example. Accordingly, also in the semiconductor element 110, it is possible to improve the ESD resistance while suppressing an increase in device area.

In the case where the semiconductor element 110 is used for the semiconductor device 60, the conductor 34 and the resistor 35 are deformed at least either thermally or mechanically after the semiconductor element 110 is provided on the mounting substrate 62. Thus, at least a part of the conductor 34 contacts the gate pad 33 to short-circuit the electric connection between the gate pad 33 and the conductor 34. Thus, the capacitance and/or resistance that interfere with the high-speed operation of the semiconductor element 110 can be reduced and the adverse effects, such as characteristic degradation, can be suppressed.

In this manner, also in the semiconductor element 110, as with the semiconductor element 10, it is possible to improve the ESD resistance while suppressing the interference with the operation of the device and/or an increase in device area.

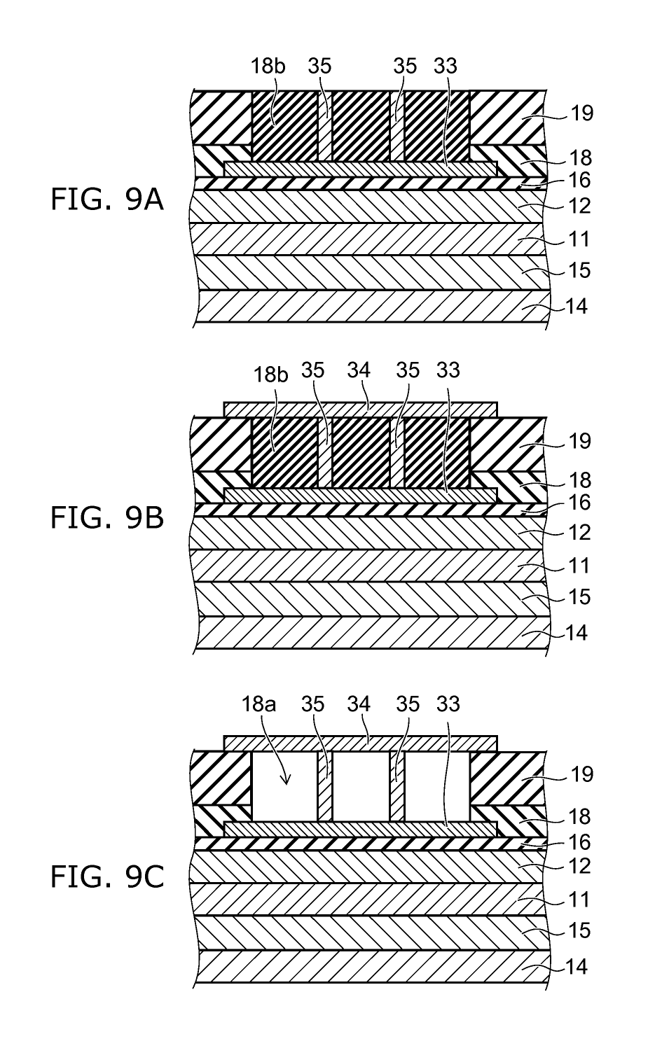

FIG. 9A to FIG. 9C are cross sectional views schematically showing the order of the manufacturing processes of the semiconductor element according to the second embodiment.

As shown in FIG. 9A, after formation of the sacrifice layer 18b according to a procedure similar to the procedure of the semiconductor element 10, a part of the sacrifice layer 18b is removed and a resistive material is embedded therein to form the columnar resistor 35, for example.

As shown in FIG. 9B, the conductor 34 is formed on the sacrifice layer 18b and the resistor 35.

As shown in FIG. 9C, the sacrifice layer 18b is removed to hollow out the inside of the opening 18a.

Thus, the semiconductor element 110 is completed.

### Third Embodiment

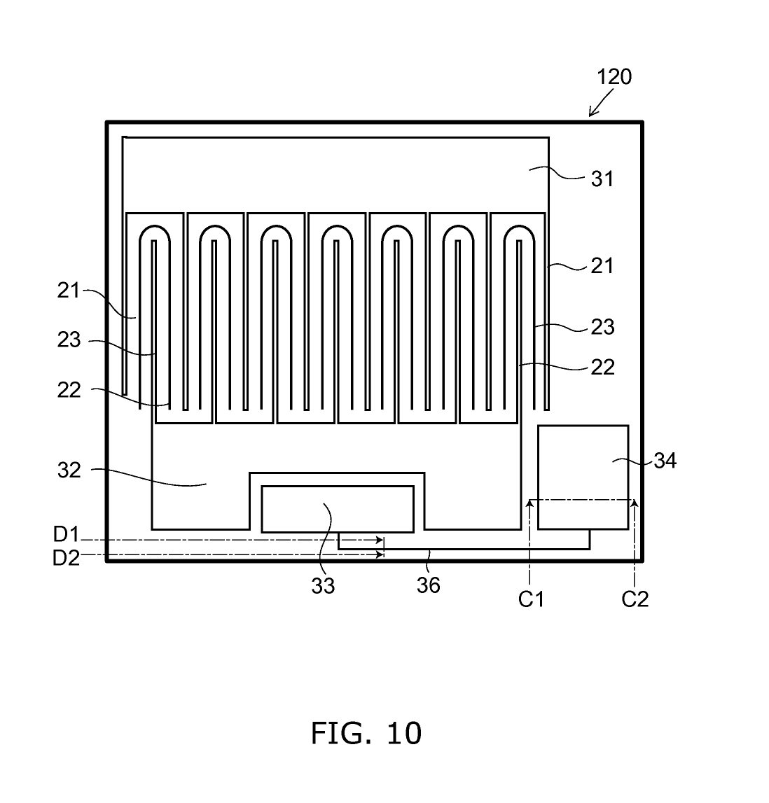

FIG. 10 is a plan view schematically showing a semiconductor element according to a third embodiment.

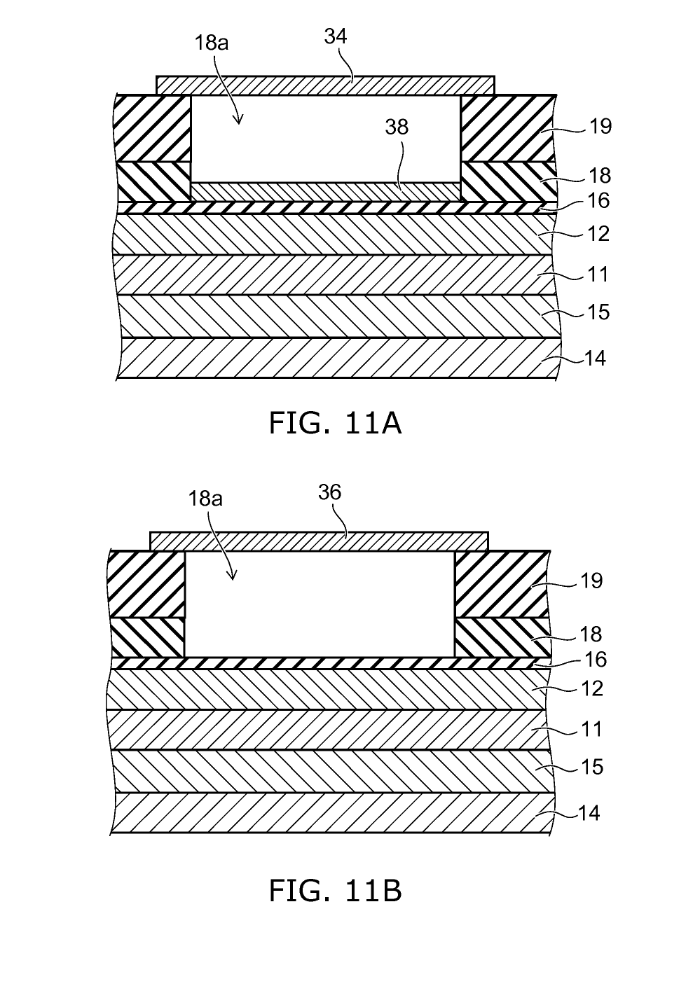

FIG. 11A and FIG. 11B are partial sectional views schematically showing a part of the semiconductor element according to the third embodiment.

FIG. 11A schematically shows the cross section along a C1-C2 line of FIG. 10.

FIG. 11B schematically shows the cross section along a D1-D2 line of FIG. 10.

As shown in FIG. 10, FIG. 11A and FIG. 11B, in a semiconductor element 120, the opening 18a and the conductor 34 are provided at a position where they do not overlap on the gate pad 33. In the semiconductor element 120, the opening 18a and the conductor 34 do not oppose the gate pad 33.

In the semiconductor element 120, the conductor 34 is electrically connected to the gate pad 33 via an interconnection 36. Moreover, in the semiconductor element 120, a conductive film 38 is provided under the conductor 34. In other words, the conductive film 38 is provided inside the opening 18a. The conductive film 38 opposes the insulating film 18, the insulating films 19, or a stacked film thereof, or opposes the conductor 34 with a space therebetween. In the semiconductor element 120, the conductor 34 is capacitively coupled with the conductive film 38. The conductive film 38 is electrically connected to the ground, for example. The conductive film 38 is electrically connected to the source electrode 22, for example. The conductive film 38 may be floating, for example.

The conductive film 38 is provided as required, and can be omitted. In the case where the conductive film 38 is omitted, the conductor 34 is capacitively coupled with, for example, the gate insulating film 16, the second semiconductor layer 12, or the like. Moreover, in a part of the lower portion of the interconnection 36 for connecting the gate pad 33 and the conductor 34, a gap is provided by the opening 18a that is provided in the insulating film 18, the insulating film 19, or a stacked film thereof. In other words, the opening 18a extends under the interconnection 36.

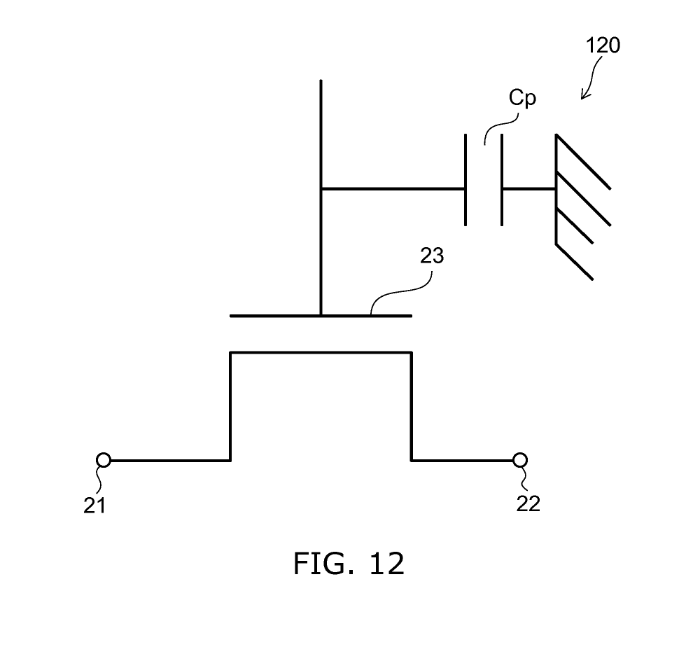

FIG. 12 is an equivalent circuit diagram schematically showing the semiconductor element according to the third embodiment.

As shown in FIG. 12, the protection capacitor Cp electrically connected to the gate electrode 23 is provided in the semiconductor element 120. The protection capacitor Cp is formed by capacitive coupling between the conductor 34 and the conductive film 38. In this manner, in the semiconductor element 120, the conductor 34 forms the protection capacitor Cp along with the conductive film 38. As described above, the conductive film 38 may be omitted. However, the conductive film 38 is provided in the semiconductor element 120. Thus, for example, the capacitance of the protection capacitor Cp can be increased further.

As described above, even with the semiconductor element 120 having the opening 18a and the conductor 34 provided at a position where they do not overlap on the gate pad 33, the protection capacitor Cp electrically connected to the gate electrode 23 can be formed. Accordingly, the ESD resistance can be improved also in the semiconductor element 120. When compared with the case where a protection diode is separately provided, the device area will not increase and the manufacturing process can be also simplified.

In the case where the semiconductor element 120 is used for the semiconductor device 60, the gate pad 33 and the conductor 34 are electrically insulated from each other, for example, by cutting the interconnection 36 after providing the semiconductor element 120 on the support unit 63 of the mounting substrate 62. Thus, the capacitance of the protection capacitor Cp that interferes with the high-speed operation of the semiconductor element 110 can be reduced and the adverse effects, such as characteristic degradation, can be suppressed.

In this manner, also in the semiconductor element 120, as with the semiconductor element 10, it is possible to improve the ESD resistance while suppressing the interference with the operation of the device and/or an increase in device area. Because a procedure for forming the opening 18a and the conductor 34 at a position where they do not overlap on the gate pad 33 can be substantially the same as the procedure in the case of the semiconductor element 10, the description here is omitted.

The method for reducing the capacitance of the protection capacitor Cp is not limited to the cutting of the interconnection 36. For example, the conductor 34 may be deformed at least either thermally or mechanically and then be destroyed or removed.

In each of the above described embodiments, a HEMT has been described as the semiconductor element. The semiconductor element according to each of the above described embodiments is not limited to the HEMT, but may be a lateral MOSFET, for example. In the case where the semiconductor element is the MOSFET, the second semiconductor layer 12 can be omitted, for example. Moreover, in each embodiment described above, the conductor 34 is provided only in the gate pad 33. Not limited thereto, for example the conductor 34 similar to the gate pad 33 may be provided for each of the drain pad 31 and source pad 32. Thus, the ESD resistance can be improved further.

According to the embodiment, there are provided a semiconductor element and a semiconductor device capable of improving the ESD resistance while suppressing the interference with the operation of the device and/or an increase in device area, a method for manufacturing the semiconductor element, and a method for manufacturing the semiconductor device.

Hereinabove, exemplary embodiments of the invention are described with reference to specific examples. However, the invention is not limited to these specific examples. For example, one skilled in the art may similarly practice the invention by appropriately selecting specific configurations of components included in the semiconductor element and the semiconductor device, such as the first semiconductor layers, second semiconductor layers, first electrodes, second electrodes, control electrodes, pad units, insulating layers, conductors, resistors, mounting substrates, support units, wiring electrodes, wirings, and interconnections from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor elements, semiconductor devices, methods for manufacturing semiconductor element, and methods for manufacturing semiconductor device practicable by an appropriate design modification by one skilled in the art based on the semiconductor elements, the semiconductor devices, the methods for manufacturing semiconductor element, and the methods for manufacturing semiconductor device described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor element, comprising:
a first semiconductor layer;
a second semiconductor layer provided on the first semiconductor layer;
a first electrode provided on the second semiconductor layer;
a second electrode provided on the second semiconductor layer;
a control electrode provided on the second semiconductor layer;
a pad unit provided on the second semiconductor layer, the pad unit being electrically connected to the control electrode;
an insulating layer provided on the second semiconductor layer, the insulating layer having an opening; and
a conductor provided on the insulating layer, the conductor covering at least a part of the opening.

2. The element according to claim 1,
wherein the first semiconductor layer is joined to the second semiconductor layer by a heterojunction.

3. The element according to claim 2, wherein
the first semiconductor layer includes Alₓ₁Ga₁₋ₓ₁N (0≦x1<1), and
the second semiconductor layer includes Alₓ₂Ga₁₋ₓ₂N (x1<x2<1).

4. The element according to claim 1, wherein
the opening is provided on the pad unit, and
the conductor opposes the pad unit.

5. The element according to claim 4, wherein the conductor is capacitively coupled with the pad unit.

6. The element according to claim 4, wherein the opening exposes at least a part of the pad unit.

7. The element according to claim 1, further comprising a resistor,
the opening being provided on the pad unit,
the conductor opposing the pad unit, and
the resistor being provided between the conductor and the pad unit, the resistor being electrically connected to each of the conductor and the pad unit.

8. The element according to claim 1, further comprising an interconnection electrically connecting the pad unit and the conductor,
the opening and the conductor not overlapping on the pad unit.

9. The element according to claim 8, further comprising a conductive film provided inside the opening, the conductive film opposing the conductor.

10. The element according to claim 9, wherein the conductor is capacitively coupled with the conductive film.

11. The element according to claim 8, wherein the opening extends under the interconnection.

12. The element according to claim 1, further comprising an insulating film provided on the second semiconductor layer,
the control electrode being provided on the insulating film.

13. A semiconductor device, comprising:
a substrate including a support unit and a wiring electrode;
a semiconductor element provided on the support unit and including:
a first semiconductor layer;
a second semiconductor layer provided on the first semiconductor layer;
a first electrode provided on the second semiconductor layer;
a second electrode provided on the second semiconductor layer;
a control electrode provided on the second semiconductor layer;
a pad unit provided on the second semiconductor layer, the pad unit being electrically connected to the control electrode; and
an insulating layer provided on the second semiconductor layer, the insulating layer having an opening on the pad unit; and
a wiring electrically connecting the wiring electrode and the pad unit.

14. The device according to claim 13, wherein the semiconductor element further includes a conductor provided on at least a part of the pad unit.

15. The device according to claim 14, wherein the conductor is in contact with the pad unit.

16. A semiconductor device, comprising:
a substrate including a support unit and a wiring electrode;
a semiconductor element provided on the support unit and including:
a first semiconductor layer;
a second semiconductor layer provided on the first semiconductor layer;
a first electrode provided on the second semiconductor layer;
a second electrode provided on the second semiconductor layer;
a control electrode provided on the second semiconductor layer;
a pad unit provided on the second semiconductor layer, the pad unit being electrically connected to the control electrode;
an insulating layer provided on the second semiconductor layer, the insulating layer having an opening; and
at least one of a conductor and a conductive film, the conductor being provided on the insulating layer and covering at least a part of the opening, the conductive film being provided on the second semiconductor layer inside the opening; and
a wiring electrically connecting the wiring electrode and the pad unit.

17. A method for manufacturing a semiconductor element, comprising:
forming a first semiconductor layer on a substrate;
forming a second semiconductor layer on the first semiconductor layer;
forming a first electrode and a second electrode on the second semiconductor layer;
forming a control electrode on the first semiconductor layer;
forming a pad unit provided on the second semiconductor layer and electrically connected to the control electrode;
forming an insulating layer having an opening on the first semiconductor layer; and
forming a conductor on the insulating layer, the conductor covering at least a part of the opening.

18. A method for manufacturing a semiconductor device, comprising:
providing a semiconductor element on a mounting substrate;
the mounting substrate including a support unit and a wiring electrode, and
the semiconductor element including:
a first semiconductor layer;
a second semiconductor layer provided on the first semiconductor layer;
a first electrode provided on the second semiconductor layer;
a second electrode provided on the second semiconductor layer;
a control electrode provided on the second semiconductor layer;
a pad unit provided on the second semiconductor layer, the pad unit being electrically connected to the control electrode;
an insulating layer provided on the second semiconductor layer, the insulating layer having an opening; and
a conductor provided on the insulating layer, the conductor covering at least a part of the opening,
the semiconductor element being provided on the support unit;
short-circuiting or insulating an electric connection between the pad unit and the conductor; and
electrically connecting the wiring electrode and the pad unit using a wiring.

19. The method according to claim 18, wherein
the opening is provided on the pad unit, and
the short-circuiting or insulating the electric connection between the pad unit and the conductor includes short-circuiting the pad unit and the conductor by deforming the conductor at least either thermally or mechanically and bringing the conductor into contact with the pad unit.

20. The method according to claim 18, wherein
the semiconductor element further includes an interconnection electrically connecting the pad unit and the conductor,
the opening and the conductor do not overlap on the pad unit, and
the short-circuiting or insulating the electric connection between the pad unit and the conductor includes electrically insulating the pad unit and the conductor from each other by cutting the interconnection electrically connecting the pad unit and the conductor.
